(19) United States
(12) Patent Application Publication
(10) Pub. No.: US 2025/0045480 A1
(43) Pub. Date: Feb. 6, 2025

(54) DETERMINING COMPLIANCE AND UPDATING DATA MODELS BASED ON MODEL STANDARDS

(71) Applicant: JPMorgan Chase Bank, N.A, New York, NY (US)

(72) Inventors: Deepak JAYADAS, Newark, DE (US); Saurabh GUPTA, Secaucus, NJ (US); Deepak JHA, Bournemouth (GB); Christopher GORDON, Glasgow (GB)

(73) Assignee: JPMorgan Chase Bank, N.A, New York, NY (US)

(21) Appl. No.: 18/229,653

(22) Filed: Aug. 2, 2023

(51) Int. Cl. G06F 30/20

(52) U.S. Cl. CPC G06F 30/20

(57) ABSTRACT

In one example, a method for updating data models includes selecting a data model standard with which the data model is to comply based on attributes identified therein. The method further includes identifying a set of attributes required by the standard, but not present in the data model, and identifying at least one highest priority change to apply to the data model to increase compliance of the data model with the standard, based on weightings of priority of the set of attributes. The method further includes visually presenting a request for approval to apply the at least one highest priority change to the data model, and applying the at least one highest priority change to the data model and updating at least one of the weightings of priority based on whether the response comprises approval to apply the at least one highest priority change.

### BACKGROUND

Data models provide representations of the behavior of real-world systems. Data models are often used as a basis for the derivation of predictions of future behavior of real-world systems, and to train machine learning systems to generate such predictions. A variety of organizations, including government departments, businesses and research institutions, often maintain large libraries of numerous data models. Ensuring the compatibility of data models with processing tools, and enabling the sharing of data models between organizations often requires that standards be created and maintained that define various aspects of data models, such as the manner in which data values are represented, organized and made searchable therein.

### BRIEF DESCRIPTION OF THE DRAWINGS

The drawings illustrate only particular examples of the disclosure and therefore are not to be considered to be limiting of their scope. The principles here are described and explained with additional specificity and detail through the use of the accompanying drawings.

FIGS. 1A, 1B, 1C and 1D, taken together, illustrate a system to update data models to comply with at least one standard according to examples of the present disclosure.

FIG. 2 illustrates aspects of automatically selecting curated data models of a database to be updated according to an example of the present disclosure.

FIGS. 3A, 3B and 3C, taken together, illustrate aspects of a first pass of analyzing and applying changes to a data model according to examples of the present disclosure.

FIGS. 4A and 4B, taken together, illustrate aspects of commencing a second pass of analyzing a data model to identify textual attributes thereof according to examples of the present disclosure.

FIG. 5 illustrates aspects of generating recommendations for a second pass of changes to apply to a data model according to an example of the present disclosure.

FIG. 6 illustrates aspects of retrieving approval and/or disapproval for changes to apply to a data model according to an example of the present disclosure.

FIGS. 7A, 7B and 7C, taken together, illustrate aspects of machine learning based on received indications of approvals and/or disapprovals for changes to apply to a data model according to examples of the present disclosure.

FIG. 8 illustrates aspects of a second pass of applying changes to a data model according to an example of the present disclosure.

### DETAILED DESCRIPTION

Over time, it is often necessary to update the standards for data models in response to the ever-changing ways in which data models are used, and each update to a standard may necessitate the updating of whole libraries of numerous related data models to meet those updated standards. Such updates to such standards often go hand-in-hand with updating the processing tools used with data models, thereby creating issues of compatibility between data models and such tools that ultimately must be addressed by applying the same updates to whole libraries of data models relatively quickly.

Unfortunately, the updating of large libraries of numerous data models can consume considerable time and other resources, and can be particularly inefficient and error-prone to do manually.

The present disclosure addresses the foregoing by providing a method, system and computer program product for efficiently updating data models within large libraries. Changes to standards are employed as a trigger to the automated identification and updating of data models that are affected. Machine learning is used to increase the efficiency with which such updating is performed by automatically identifying particular changes to data models that are higher in priority than others. AI/ML (Artificial Intelligence/Machine Learning) is also used to identify when changes to data models are necessitated by changes in which aspects of data models are most important to maintain in compliance with standards. The system can automate the tasks for model creation, governance, maintenance and reverse-engineering, the system is self-learning, and leverages AI/ML to train and learn modeling patterns.

In this manner, the updating of data models is performed in a more efficient manner that focuses on which data models need to be updated, and on which updates are of higher value.

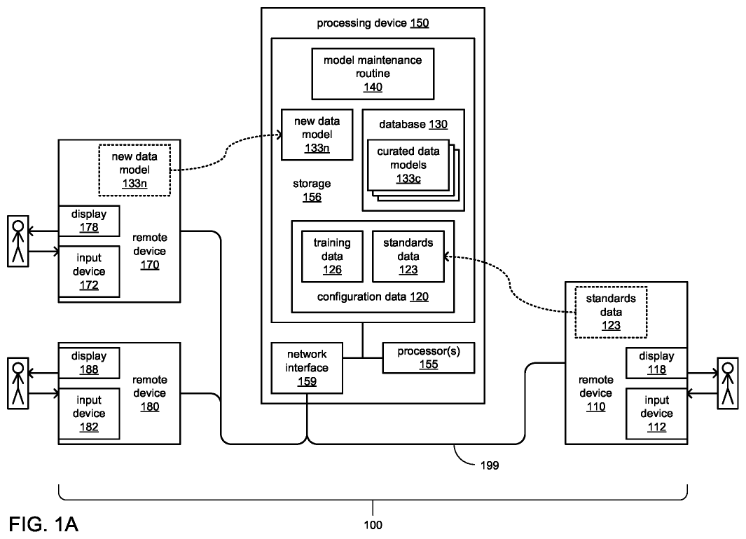

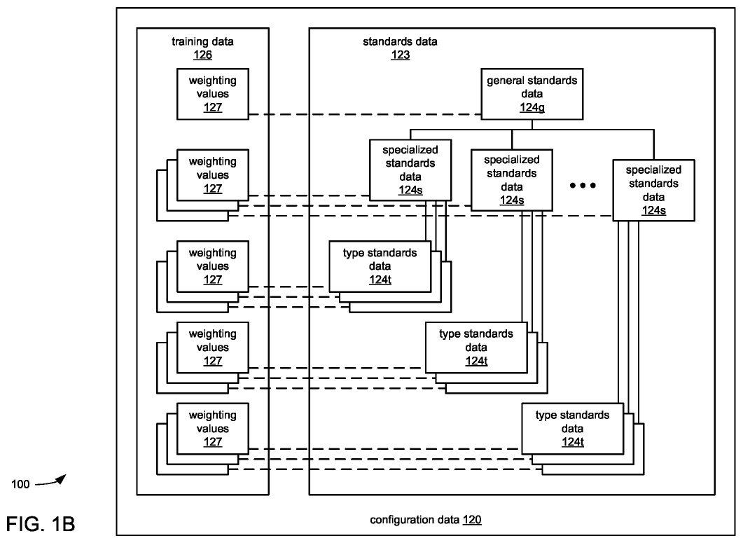

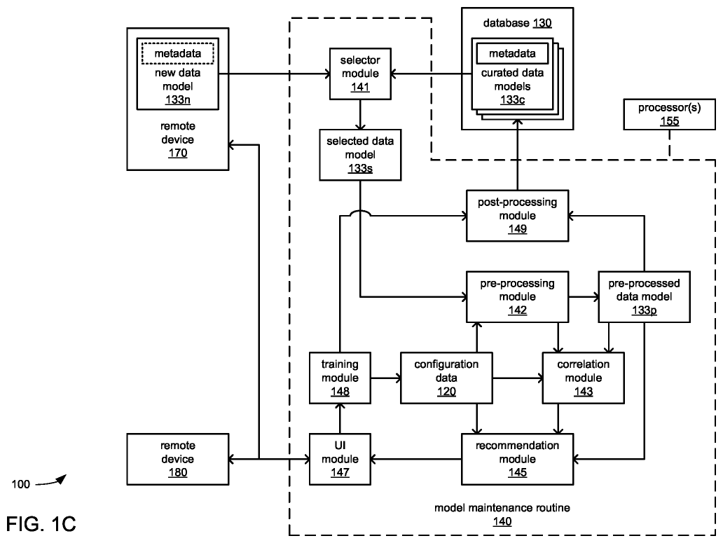

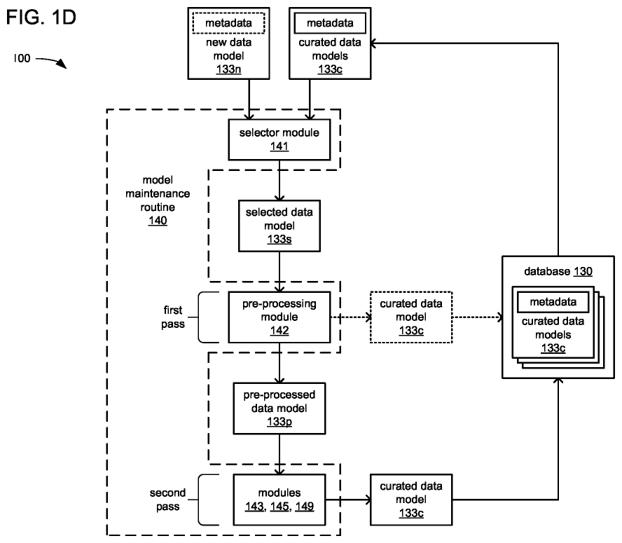

FIGS. 1A-D, taken together, present block diagrams of a system 100 in which a model maintenance routine 140 may be executed to apply standards to new and/or existing data models according to examples of the present disclosure. In so doing, machine learning may be employed to learn aspects of the application of the various standards, and to thereby increase the efficiency with which that application of standards is automated.

In the example of FIG. 1A, the system 100 may include a processing device 150, and/or remote devices 110, 170, 180 that are coupled via a network 199. In the example of FIG. 1B, the configuration data 120 may store information concerning the various standards, and concerning what has been learned via machine learning about applying the various standards. FIG. 1C depicts aspects of the execution of the model maintenance routine 140 to perform the application of standards to new and/or existing data models according to examples of the present disclosure. FIG. 1D depicts aspects of a two-pass approach to the application of standards to data models that may be performed through execution of the model maintenance routine 140 according to examples of the present disclosure.

Turning to FIG. 1A, the processing device 150 may maintain a database 130 of curated data models 133c. The processing device 150 may also temporarily store copies of new data models 133n that are in preparation for being stored in the database 130 as more of the curated data models 133c. As will be explained in greater detail, each of the curated data models 133c within database 130 may be required to have particular formatting attribute(s), particular organizational attribute(s), particular data encoding attribute(s), and/or still other particular attribute(s) to be compliant with at least one standard for data models.

The processing device 150 may also be the computing device in which the model maintenance routine 140 is executed to automate the application of standards to the data models 133c and/or 133n. As will be explained in greater detail, the application of standards to the curated data models 133c may be performed as part of updating the curated data models 133c to conform to updated versions of standards in response to updates that are made to the standards over time. In contrast, the application of standards to the new data models 133n may be performed as part of preparing the new data models 133n for being added to the database as more curated data models 133c.

The processing device 150 may include at least one processor 155, a storage 156, and/or a network interface 159 that couples the processing device 150 to the network 199. As depicted, the storage 156 may store the model maintenance routine 140, the database 130, the configuration data 120, and/or a copy of at least one new data model 133n that may be received via the network 199 from other device(s) for addition to the database 130.

As depicted, the configuration data 120 may include standards data 123 and/or training data 126. The standards data 123 may include specifications of the standards that are to be applied to the data models 133c and/or 133n. The training data 126 may include indicators of learned aspects of applying the standards.

It should be noted that, although the configuration data 120 and the database 130 are depicted as being stored directly within the processing device 150, other implementations are possible in which the configuration data 120 and/or the database 130 may be stored within other device(s) that may be accessible to the processing device 150 via the network 199 (e.g., a network-attached storage device).

The remote devices 110, 170 and 180 serve as remote terminals by which various personnel associated with the application of standards to the data models 133c and/or 133n may interact with the system 100. Each one of the remote devices 110, 170 and 180 includes components for the provision of a user interface (UI) for various ones of such personnel, including a combination of an input device 112 and display 118, a combination of an input device 172 and display 178, and a combination of an input device 182 and display 188, respectively. However, it should be noted that still other implementations of the remote devices 110, 170 and/or 180 are possible that incorporate different types and/or combinations of components that are able to be employed to provide such a UI.

The remote device 110 may be interacted with by personnel associated with generating and/or updating the standards that are to be applied. Thus, the remote device 110 may be used to provide new versions of the standards data 123 to the processing device 150 via the network 199.

The remote device 170 may be interacted with by personnel providing new data models 133n that are each to be added to the database 130 as a new one of the curated data models 133c. As will be discussed in greater detail, such personnel may also interact with the remote device 170 to play a roll in approving and/or disapproving aspects of the application of standards to new data models 133n incorporating data that they may have provided, and/or to curated data models 133c already stored within the database 130.

The remote device 180 may be interacted with by personnel overseeing aspects of the application of standards. Thus, as a new data model 133n is being prepared for addition to the database 130, or as an existing curated data model 133c is being updated, such personnel may interact with the remote device 180 to play a roll in reviewing various aspects of the application of standards, and/or various approvals and/or disapprovals thereof by personnel interacting with the remote device 170. As will be discussed in greater detail, such reviewing may aid in ensuring consistency in the application of standards.

As will also be explained in greater detail, the inputs of approval and/or disapproval received from the remote devices 170 and/or 180 may serve as the inputs to the machine learning performed by the processing device 150 as part of executing the model maintenance routine 140.

Turning to FIG. 1B, the standards data 123 within the configuration data 120 may store information concerning multiple standards as a hierarchy. More specifically, and as depicted, specifications of a single generally applicable standard may be stored as a single instance of general standards data 124g at the top of the hierarchy. It may be that such a generally applicable standard is meant to apply to all data models that are associated with a particular organization, such as a corporation, an educational institution or a government. Thus, such a generally applicable standard may specify various aspects of data models that are widely applicable to all data models of an organization, regardless of what the subject area of each data model may be and/or in spite of implementation details of the database 130 in which a data model may be stored. Such widely applicable aspects may include such details as the manner in which data values of various currencies from around the world may be stored and/or the manner in which they may be visually presented when viewed.

Within a mid level of the hierarchy may be multiple instances of specialized standards data 124s. Each such instance may specify aspects of data models that are germane to a particular field of research or study, to a particular activity or industry, to a particular business or governmental entity, or to a particular division or department of such an entity, etc. Such specialized aspects may include a specialized glossary of terms, specialized data types, specialized data structures, etc.

Within a bottom level of the hierarchy may be multiple instances of even more specialized type standards data 124t that may each correspond to a specialized type of data model, a specialized type of database or computing device within which data models may be stored, etc. By way of example, it may be that different instances of type standards data 124t are provided to address different computing devices with different processor architectures that differ by their use of little endian encoding versus big endian encoding, or differ by their use of an ASCII character set versus a word-sized character set. There may be multiple instances of such type standards data 124t for each one of the specialized standards data 124s.

Thus, it should be understood that multiple standards may be applicable to each data model, and the combination of standards that are applicable to each data model may differ from one to another. By way of example, it may be that the most generally applicable standard associated with the general standards data 124g is applicable to all data models stored within the system 100. A single particular one of the more specialized standards 124s may be applicable to a data model, depending on what corporation, industry, department, area of research, etc. is associated with its content. And, a single particular one of the even more specialized standards associated with a single one of the type standards data 124t may be applicable based on various details of whichever type of database and/or computing device is used to store it.

The training data 126 within the configuration data 120 may store various weighting values 127 indicative of numerous aspects of the application of standards to data models that have been learned over time. As depicted, it may be that there are separate sets of weighting values 127 that specifically correspond to individual ones of the standards data 124g, 124s and/or 124t. By way of example, and as will be explained in greater detail, there may be sets of weighting values 127 that are repeatedly adjusted over time to record what has been learned concerning the relative priorities with which different aspects of a standard are applied, or the relative degree of frequency with which different attributes may be present within a data model.

It should be noted that, despite the depiction of just three levels of hierarchy of standards within the standards data 123 in FIG. 1B, what is depicted in FIG. 1B is a deliberately simplified example for purposes of illustration and for ease of understanding. More specifically, other implementations are possible with more or fewer levels. Additionally, it should be noted that other implementations are possible in which there may be more than one hierarchy of standards may be included within the standards data 123.

Turning to FIG. 1C, as depicted, the model maintenance routine 140 may include a selector module 141, a pre-processing module 142, a correlation module 143, a recommendation module 145, a UI module 147, a training module 148, and a post-processing module 149.

Execution of the selector module 141 may cause the processor(s) 155 of the processing device 150 to automatically retrieve existing curated data models 133c from the database 130 for being updated to meet new versions of various standards. In some implementations, it may be that updates made to a particular standard (e.g., through the provision of an updated version of the standards data 123) trigger the automated retrieval of ones of the curated data models 133c that are subject to that particular standard for purposes of being updated to comply with those updates. Such updates may include the addition of new attributes to a standard, and/or changes to various aspects of attributes already included within a standard. Alternatively, or additionally, such updates may include reversals or deprecations of previous ones of such additions and/or changes in a standard.

Each of the curated data models 133c may include, or be otherwise accompanied by, metadata. Such metadata may include indications of various aspects of its associated curated data model 133c and/or of the data stored therein. By way of example, the metadata may include indications of what standards are applicable to its associated curated data model 133c, and/or what attributes its associated curated data model 133c does or does not have. In implementations in which updates made to a particular standard triggers the automated retrieval and updating of a subset of the curated data models 133c, it may be that such indications of applicable standards in the metadata for each curated data model 133c serves as a mechanism for identifying such a subset.

Alternatively, or additionally, execution of the selector module 141 may also support the receipt of a new data model 133n, from which a new curated data model 133c may be generated for addition to the database 130. Again, such a new data model 133n may be received by the system 100 through the remote device 170.

It may be that at least some new data models 133n also include, or are accompanied by, metadata. However, it is envisioned that new data models 133n may adhere to few, if any, of the standards that are applied to the curated data models 133c. Thus, it may be that the metadata that may accompany a new data model 133n may similarly adhere to few, if any, of such standards, such that its content may be considerably different from the content of the metadata of each of the curated data models 133c.

Regardless of whether a new data model 133n or an existing curated data model 133c is selected to become a selected data model 133s, execution of the pre-processing module 142 may cause the processor(s) 155 of the processing device 150 to perform an initial analysis of various aspects of the selected data model 133s. From those initial analyses a determination may be made concerning which standard(s) are applicable to the selected data model 133s. As will be explained in greater detail, which initial analyses are performed to make such a determination may depend on whether the selected data model 133s includes (or is otherwise accompanied by) metadata.

Regardless of the exact manner in which the applicable standard(s) are identified, further initial analyses may be performed to identify a template that is associated with those standard(s), and that the selected data model 133s should comply with. Presuming such a template is identified, still further initial analyses may be performed to identify aspects of the selected data model 133s that do not conform to that template, and this may cause various initial changes to be automatically applied to the selected data model 133s based on the results of such analyses. Such initial changes may include formatting changes, data value normalization changes, data type changes, etc. In so doing, a pre-processed data model 133p is generated from the selected data model 133s. In performing such initial analyses and/or in applying such initial changes, the processor(s) 155 may be caused to refer to the configuration data 120 for indications of initial analyses to be performed, standards that may be applicable, associated templates and/or what initial changes are to be applied.

Following the performance of such initial analyses and/or such application of such initial changes, the correlation module 143 may be provided with indications of the results of the initial analyses (including what standards are applicable), indications of what initial changes were applied, and a copy of the resulting pre-processed data model 133p. Execution of the correlation module 143 may cause the processor(s) 155 of the processing device 150 to compare at least some of the terminology present within the pre-processed data model 133p to sets of terms within glossaries stored within the configuration data 120 that are associated with the applicable standards. Where matches are found, indications of those matches may be provided to the recommendation module 145. It should be noted that such indications of matches may include indications of a degree of similarity in terminology for each match.

In executing the recommendation module 145, the processor(s) 155 of the processing device 150 may be caused to retrieve, from the configuration data 120, indications of what additional changes may be prompted by the match(es) in terminology that were identified by the correlation module 143. Along with indications of what additional change(s) may be prompted by each match, the processor(s) 155 may also be caused to retrieve indications of a minimum degree of similarity required to trigger each additional change, and/or indications of learned relative weightings of the relative degree of priority of each such additional change. It should be noted that at least some of such additional changes that may be triggered may include replacing non-standardized terminology with terminology that does comply with the applicable standards.

Further execution of the recommendation module 145 may cause the processor(s) 155 to employ such indications of degree of similarity together with such indications of relative priority to select up to a pre-determined quantity of highest ranked additional changes to propose be applied to the pre-processed data model 133p. In some implementations, it may be that just the single highest ranked additional change is recommended. In other implementations, it may be that up to 10 (or up to some other pre-determined quantity) of the highest ranked additional changes are recommended.

Regardless of the quantity of highest-ranking additional changes that are automatically selected to be proposed, indications of those recommendations may be provided to the UI module 147. In executing the UI module 147, the processor(s) 155 of the processing device 150 may be caused to operate the network interface 159 to cooperate with the remote devices 170 and/or 180 through the network 199 to provide user interfaces by which the recommended additional change(s) are presented to operators of those remote devices.

More specifically, an operator of the remote device 170 may be presented with proposals of at least one highest ranked recommendations of additional changes, along with a prompt for input concerning which one(s) of those proposed additional change(s) are approved for being applied (if any). The processor(s) 155 of the processing device 150 may then be caused to await a response indicative of such input.

Upon receiving such input from the remote device 170, further execution of the UI module 147 may cause the processor(s) 155 to operate the network interface 159 to provide, to the remote device 180, both the indications of such proposed additional change(s), and indications of which one(s) have been approved. Thus, an operator of the remote device 180 may be presented with the same proposal of the at least one highest ranked recommendation, along with indications of which one(s) have been approved, and a prompt for input of any changes concerning which one(s) should be approved. The processor(s) 155 may then be caused to await a response indicative of such input.

Upon receiving such input from the remote device 180, indications of what additional change(s) were recommended, along with indications of which additional change(s) were ultimately approved (if any) may be provided to the training module 148. In executing the training module 148, the processor(s) 155 of the processing device 150 may be caused to update the configuration data 120 with revisions to the learned relative weightings of the relative degree of priority of each of the additional change(s) that were proposed by the recommendation module 145. As will be explained in greater detail, there may also be revisions made to the learned relative weightings of the relative degree of frequency of what standards have been found to be applicable, and/or of the relative degree of frequency of what templates are used. In this way, the system 100 may be caused to learn various aspects of the application standards to data models.

In addition to the training module 148, indications of what proposed additional change(s) have been approved (if any) may also be relayed to the post-processing module 149. Execution of the post-processing module 149 may cause the processor(s) 155 of the processing device 150 to apply the approved additional change(s) to the pre-processed data model 133p before it is stored within the database 130 as a curated data model 133c.

As more explicitly depicted in FIG. 1D, the various analyses of data models and the various performances of changes thereto may be performed in two distinct passes. More specifically, the various aforedescribed initial analyses and initial changes caused by execution of the pre-processing module 142 may be part of a first pass of analyses of the selected data model 133s and of changes thereto to generate a pre-processed data model 133p therefrom. Then, the various aforedescribed additional analyses and additional changes caused by execution of the modules 143, 145, 148 and/or 149 may be part of a second pass of analyses of the pre-processed data model 133p and of changes thereto to generate a curated data model 133c therefrom.

As will be explained in greater detail, the initial analyses and/or changes of the first pass may be based on identifying syntactic, formatting, organizational and/or other aspects of a data model, and based less on textual attributes. In contrast, the additional analyses and/or changes of the second pass may be based on identifying textual attributes and correlating those textual attributes to other attributes. In this way, the first pass may serve to prepare a pre-processed data model 133p in which non-standardized formatting, syntax, organizational and/or other non-standardized aspects of a selected data model 133s are identified and changed to better conform to at least one standard before analyses based on textual attributes is performed. Such preparation performed in the first pass may aid in improving the accuracy with which textual attributes are identified and responded to in the second pass. It may be for this reason that the initial changes of the first pass are automatically performed prior to seeking indications of approval and/or disapproval of those initial changes, while the additional changes of the second pass are recommended, but not yet performed until after indications of approval and/or disapproval have been sought and received.

In some implementations, where a curated data model 133c within the database 130 is selected to be the selected data model 133s, it may be that at least initial changes of the first pass are applied to that curated data model 133c in situ within the database 130. This may be deemed preferable to incurring the consumption of processing and/or storage resources that would be needed to retrieve that curated data model 133c from within the database 130 and store a separate copy thereof outside of the database 130 in preparation for applying the initial changes to that copy. As will be explained in greater detail, there may be circumstances in which an evaluation of the degree of compliance of a selected data model 133s results in a determination that just initial changes of the first pass are to be applied, while additional changes of the second pass are to be forgone. In such a situation, where the selected data model 133s is a curated data model 133c, the fact that the initial changes of the first pass were applied in situ enables the consumption of further processing and/or storage resources to store a copy of that curated data model 133c back within the database 130 to also be avoided.

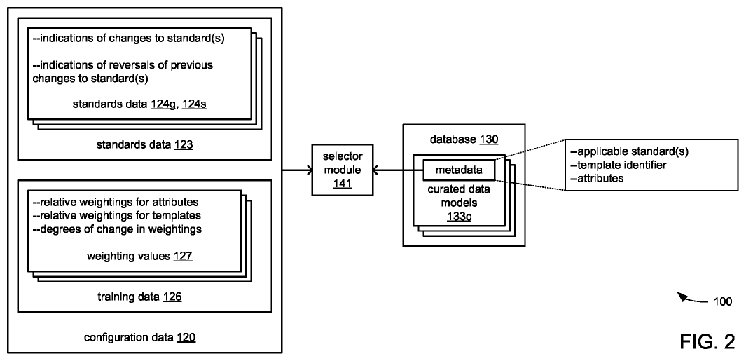

FIG. 2 presents aspects of the operation of the selector module 141 to automatically select individual ones of the curated data models 133c from the database 130 for purposes of being updated according to examples of the present disclosure.

In executing the selector module 141, the processor(s) 155 of the processing system 150 may be caused to analyze contents of the metadata within each curated data model 133c to identify ones of the curated data models 133c that are to be selected to be updated. As previously discussed, standards may be updated from time to time. Among such updates may be the addition of requirements for new attributes to be added to standardized templates for data models, and/or changes to such attributes. Alternatively, or additionally, among such updates may be changes to requirements for standardized templates that result in the removal of attributes. Also alternatively or additionally, among such updates may be reversals of previous changes to standardized templates that may result in the removal of an attribute that had been previously required to be added, and/or that result in the reversal of a previously required change to an attribute or a previously required change from one attribute to another.

In identifying which curated data models 133c are subject to any such updates, the processor(s) 155 may be caused to retrieve indications from each instance of the standards data 124g and/or 124s of which standard(s) have been recently updated. The processor(s) 155 may then be caused to check the indications within the metadata of each curated data model 133c of which standards are applicable to each. Where a curated data model 133c is subject to a particular standard that is subject to such an updated, that curated data model 133c may be automatically selected to become the selected data model 133s to be updated.

As an alternative to, or in addition to, such automated selection of curated data models 133c based on updates to standards, execution of the selector module 141 may cause the processor(s) 155 to identify ones of the curated data models 133c that are to be updated in response to changes in relative weightings associated with various attributes and/or templates associated with at least one standard. This is to address the fact that, even where a standard has not been changed, the degree to which various requirements of a standard are adhered to may change over time. Changing circumstances may result in changes in the way in which various ones of the curated data models 133c are used, and this may cause a change in which attributes are deemed to be more important than others such that there may be corresponding changes in the relative priorities concerning which attributes are maintained more rigidly in compliance with standards.

In identifying which curated data models 133c are subject to any such change in relative weightings for attributes and/or templates, the processor(s) 155 may be caused to retrieve, from sets of weighting values 127 associated with each of the standards, indications of degrees of change in weighting(s) over a predetermined period of time (e.g., over the preceding day, over a preceding quantity of days, etc.). Such weighting values 127 may specify relative weightings indicative of degree of inclusion and/or degree of compliance for individual attributes. Alternatively, or additionally, such weighting values 127 may specify relative weightings indicative of frequency of use of individual templates.

Upon identifying which weighting values of changed to a degree meeting a predetermined threshold, the processor(s) 155 may then be caused to check the indications within the metadata of each curated data model 133c to determine which curated data models 133c are based on a template and/or include an attribute that is associated with such a degree of change in a relative weighting. Where a curated data model 133c is so associated with such a change in a relative weighting, that curated data model 133c may be automatically selected to become the selected data model 133s to be updated.

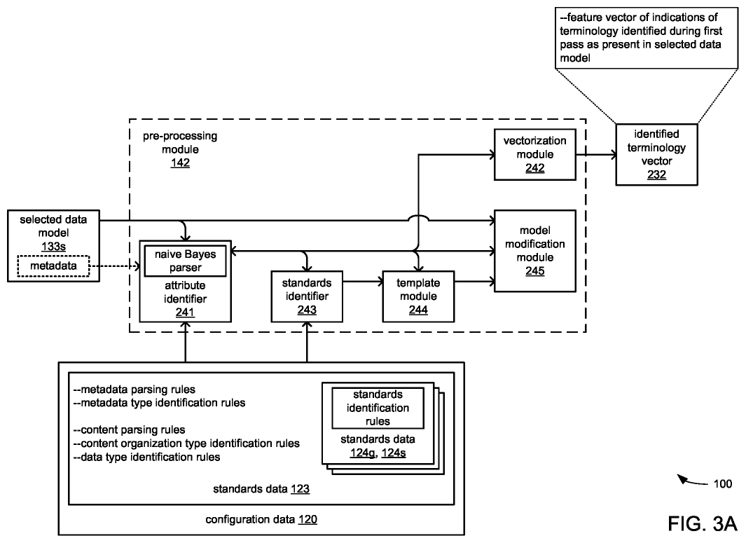

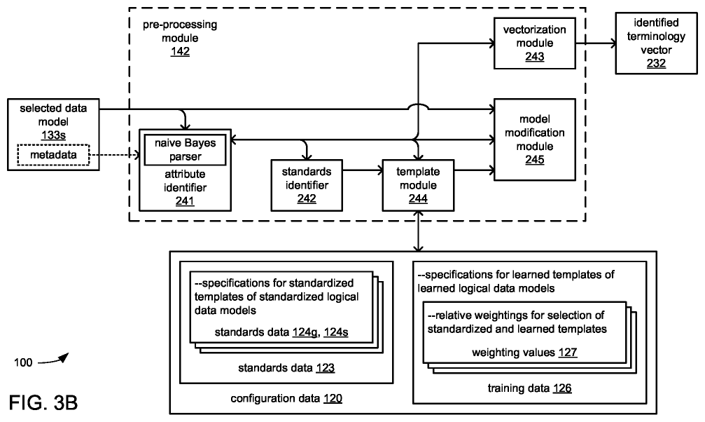

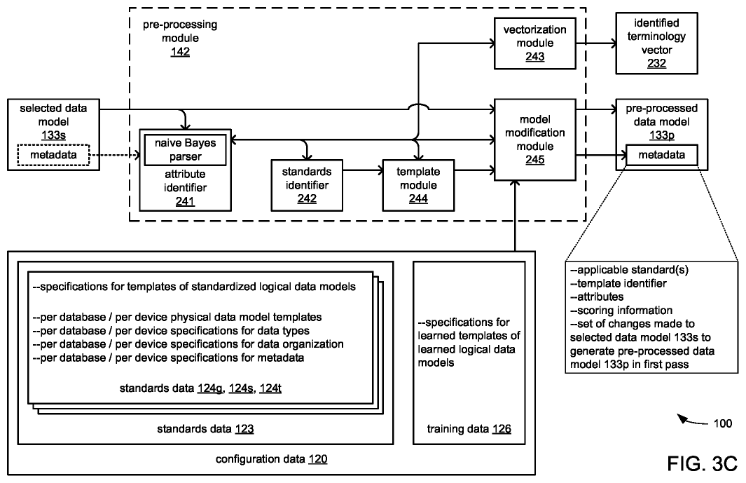

FIGS. 3A-C present aspects of the operation of the pre-processing module 142 to perform the first pass of analyses and changes according to examples of the present disclosure. In the example of FIGS. 3A-C, the pre-processing module 142 may include an attribute identifier 241, a vectorization module 242, a standards identifier 243, a template module 244, and a model modification module 245.

Turning to FIG. 3A, execution of the attribute identifier 241 may cause the processor(s) 155 of the processing device 150 to begin the performance of the initial analyses of the first pass by analyzing the selected data model 133s to identify various attributes thereof. Such initial analyses may include parsing the metadata and/or the contents of the selected data model 133s, and/or various analyses of the organization and/or data value representation details of the contents within the selected data model 133s.

As previously discussed, it may be that the application of standards to the curated data models 133c results in the curated data models 133c including (or being otherwise accompanied by) metadata that is descriptive of various attributes. Thus, where a curated data model 133c or a new data model 133n that includes metadata is selected to be the selected data model 133s, the initial analyses thereof may be based primarily on such parsing of metadata. However, such parsing of metadata may also be accompanied by parsing the contents of the selected data model 133s.

As depicted, the attribute identifier 241 may include a naive Bayes parser implementing probabilistic classifiers based on Bayes' theorem to parse metadata (if present) and/or the contents of the selected data model 133s. The processor(s) 155 may be caused to retrieve indications of what textual attributes (e.g., text labels for rows and/or columns, text employed in indexing schemes, etc.) and/or other similar attributes (e.g., various uses of punctuation marks, individual text characters, punctuation marks, etc.) are to be parsed for from the standards data 123. The probabilistic classification that is performed may generate degrees of probability of the presence of each attribute.

As also previously discussed, while some new data models 133n may include (or may be otherwise accompanied by) metadata, other new data models 133n may not. Also, where metadata for a new data model 133n is available, the contents, syntax and/or organization of contents within the metadata of a new data model 133n may not conform to any of the standards that are applied to the curated data models 133c, which may make parsing the metadata more difficult. Thus, where a new data model 133n without metadata or with non-standardized metadata is selected to be the selected data model 133s, the performance of the initial analyses of the first pass may not begin with parsing metadata. Instead, the initial analyses thereof may be based primarily on other types of analyses of the data values and/or the organization of data values within the selected data model 133s. Such other types of analyses may entail the identification of delimiters (including non-text characters, symbols, etc.), spacing and/or other forms of syntax (e.g., sequences of data values) that define indexing schemes, labels, rows, columns and/or individual storage locations within the selected data model 133s. However, such other types of analyses may still be accompanied by parsing of the contents of the selected data model 133s.

Regardless of which exact analyses are performed in the first pass on the selected data model 133s and/or its metadata, indications of what textual attributes are identified as being present therein may be relayed to the vectorization module 242. Among such identified textual attributes may be labels for rows, columns, indices, etc. that, as a result of having been identified as present, provide various indications of other aspects of the contents and/or the organization of the contents within the selected data model 133s. Stated differently, it may be that there is a correlation (or at least a degree of likelihood of correlation) between the presence of a particular textual attribute (e.g., particular terminology) and the presence of another attributes.

In executing the vectorization module 242, the processor(s) 155 of the processing device 150 may be caused to generate at least one identified terminology vector 232 indicative of the terminology identified as being present. More specifically, in some implementations, the vectorization module 242 may implement a form of term frequency-inverse document frequency (TD-IDF) text vectorization to generate each identified terminology vector 232 as a feature vector. In such implementations, each identified terminology vector 232 may include indications of the quantity of instances of each word, abbreviation and/or other contiguous set of text characters (other than spaces and/or punctuation character) that is found to be present within the selected data model 133s relative to the overall quantity of words, abbreviations and/or other contiguous sets of text characters.

A broader set of indications of what attributes are identified as being present within the selected data model 133s and/or its metadata (if present) may also be provided to the standards identifier 243. In executing the standards identifier 243, the processor(s) 155 may be caused to retrieve various rules for identifying applicable standards from instances of the standards data 124g and/or 124s. Such rules may specify combinations of particular attributes that correlate to particular standards that may be applicable. Regardless of the exact manner of identifying applicable standards, indications of what standards are identified as being applicable to the selected data mode 133s may then be provided to the template module 244.

It should be noted that, in some implementations, at least the metadata associated with each of the curated data models 133c may include indication(s) of applicable standard(s). Thus, at least where a curated data model 133c is selected to be the selected data model 133s (and maybe in some instances in which a new data model 133n is so selected), relatively little parsing or other initial analyses may be needed to determine which standard(s) are applicable. However, in spite of the provision of such explicit indication(s) of applicable standard(s), it may be that the identification of attributes via metadata and/or other analyses is still performed to determine whether such explicit indication(s) of applicable standard(s) remains correct in view of updates that may have been made. If, based on what attributes are found to be present within the selected data model 133s, it is determined that indication(s) of applicable standards in associated metadata are no longer correct, then initial analyses to identify applicable standards may still be performed.

Turning to FIG. 3B, along with the indications of applicable standards, indications of what attributes are identified as being present within the selected data model 133s and/or its metadata (if any) may also be relayed to the template module 244. In executing the template module 244, the processor(s) 155 may be caused to use the indications of identified attributes to search for at least one existing template for data models having the same attributes. Further, the processor(s) 155 may be caused to limit the search to templates associated with the applicable standards, as earlier identified by the standards identifier 243.

Some templates may be standardized templates associated with at least one of the standards for data models. Again, each instance of standards data 124g and/or 124s may include specifications for standardized templates, and such specifications may be searchable based on their attributes. Alternatively, or additionally, some templates may be learned templates that have been generated over time as a result of the creation of curated data models 133c having a set of attributes that did not match the set of attributes of any of the standardized templates. The training data 126 may include specifications for each such learned template, and such specifications may also be searchable based on their attributes.

If a template among the standardized templates or among the learned templates associated with the applicable standards is found that has a set of attributes that matches the attributes identified as present within the selected data model 133s, then an identifier of that particular template may be relayed to the model modification module 245. If more than one of such templates are found, then the selection of which template to use may be based on weightings for the relative frequency of use of each of those templates.

It should be noted that the determination of whether a matching template is found may be based on a comparison of a degree of matching of attributes for each template to a pre-determined threshold minimum degree of matching. More specifically, it may be that a lack of matching of a relatively small quantity of attributes is deemed to be close enough for a template to be determined to be a match. In such implementations, it may be relative weightings representing relative degrees of priority among attributes are used to identify individual attributes that may be required to be matched versus individual attributes that may not be required to be matched for a template to be determined to be a match.

Regardless of the exact manner in which a template is determined to be a match, if no matching template is found among either of the standardized templates or the learned templates associated with the applicable standards, then the identified attributes may be used to define a new learned template that may be added to the specifications for learned templates maintained within the training data 126. Following the addition of such a new learned template to the specifications for learned templates within the training data 126, an identifier of that new learned template may be relayed to the model modification module 245.

It should also be noted that, as described above in reference to indications of applicable standard(s), the selected data model 133s may include (or be otherwise accompanied by) metadata that may include an identifier of what template the selected data mode 133s had been previously generated to adhere to. Thus, it may be that relatively little parsing or other initial analyses may need to be performed to identify a template that was at least previously determined to be a match, or that may have been specifically created to be a match. However, in spite of the provision of such an explicit indication of a template, it may be that the identified applicable standard(s) and/or the identified attributes of the selected data model 133s are still used to determine whether such an explicit identification of a template remains correct in view of updates that may have been made to at least one standard. If, based on what attributes are found to be present within the selected data model 133s, it is determined that the identification of a template in the associated metadata as a match was not correct, or is no longer correct, then the aforedescribed operations to either identify an existing standardized or learned template, or to derive a new learned template, may still be performed.

Turning to FIG. 3C, along with the identifier of the standardized or learned template that the selected data model 133s should conform to, indications of what attributes are identified as being present within the selected data model 133s and/or its metadata (if any) may also be relayed to the modification module 245. In executing the model modification module 245, the processor(s) 155 of the processing device 150 may be caused to preemptively apply at least one initial change of the first pass to the selected data model 133s to cause it to conform to that template.

More precisely, the processor(s) 155 may be caused to retrieve specifications of the identified template, and may use those specifications along with the indications of identified attributes to determine which specified aspects of the template are already complied with by the selected data model 133s, and which are not (if any). In some implementations, such determinations may entail comparing the attributes that are specified as part of the identified template to the attributes that have been identified as being present within the selected data model 133s. The processor(s) 155 may then apply at least one initial change to those non-compliant aspects (if any) of the selected data model 133s to make the selected data model 133s fully compliant with the identified template.

It should be noted that the standardized templates for which specifications may be stored within the standards data 123, and the learned templates for which specifications may be stored within the training data 126 may both be templates for logical data models. Such templates may specify higher level aspects of a data model that are not specific to a particular database and/or device used for storage, such as the type of data structure by which data values are organized, delimiters and/or other syntax used to implement such organization, bit widths of data values, data value encoding details, minimum/maximum data values, etc. Thus, the specifications for templates that are stored within the general standards data 124g, and/or within each instance of the specialized standards data 124s may be for such a higher level logical data model that is associated with the corresponding standard, and may be agnostic of lower level physical implementation details that may be unique to the choice of hardware and/or software employed in storing data models.

However, and as previously discussed, it may be that the processing device 150 or the database 130 is of a type that imposes some additional lower level requirements on the manner in which data is stored therein. This may create additional requirements of various aspects of each curated data model 133c, such as implementation details for particular data types (e.g., how to represent signed and/or unsigned integer values, big endian vs. little endian encoding, particular floating-point value encodings, particular text encodings), and/or implementation details for delimiters and/or other mechanisms used in defining portions of data structures (e.g., punctuation used as particular types of delimiters, use of spacing), etc. Such lower level details that are unique to particular types of database and/or to particular computing devices within which the curated data models 133c may be stored may be specified within the type standards data 124t.

It may be that, for each logical data model for which a specification may be stored within one of the specialized standards data 124s, there may multiple specifications for multiple corresponding physical data models that may be stored across multiple corresponding ones of the type standards data 124t. By way of example, the specifications for each one of the corresponding physical data models may provide such details as how to implement each bit width and/or each range of minimum to maximum for a data value using the particular set of data types available in a particular type of database and/or within a particular type of computing device. In effect, each one of the curated data models 133c may be an instance of a physical data model that implements a corresponding logical data model in a manner that fits a particular type of the database 130 and/or a particular type of the processing device 150.

Thus, the processor(s) 155 may also be caused to retrieve, from at least one instance of the standards data 124t, information concerning how to implement various aspects of the identified logical data model as a physical data model appropriate for the database 130 and/or appropriate for the processing device 150. In this way, the initial changes made to the selected data model 133s are made in a manner that causes the resulting pre-processed data model 133p to conform to whatever particular requirements may be imposed by the database 130 and/or by the processing device 150.

In further executing the model modification module 245, the processor(s) 155 may also be caused to retrieve portions of the identified template that specify higher level aspects of the metadata that is to be incorporated into the pre-processed data model 133p. Such higher-level aspects may include specifications for the content of the metadata and/or how it is to be organized therein. By way of example, it may be that the metadata is specified to include indications of which standards are applicable to the pre-processed data model 133p. Alternatively, or additionally, it may be that the metadata is specified to include indications of the presence and/or absence of various attributes within the pre-processed data model 133p. Also, alternatively or additionally, it may be that the metadata is specified to include indications of what initial changes have been applied to selected data model 133s to generate the pre-processed data model 133p, thereby enabling those changes to be reversed at a later time.

In a manner similar to the pre-processed data model 133p, itself, it may be that there are aspects of generating the metadata thereof that are also affected by requirements imposed by the particular type of the database 130 and/or by the particular type of the processing device 150. Thus, the specifications for physical data models that are retrieved from at least one instance of the type standards data 124t that are associated with an applicable standard may include specifications for lower level aspects of generating metadata.

It should be noted that information for use in determining what physical data model should be implemented for each selected data model 133s and/or is associated metadata may be received from various different sources. In some implementations, indications of the type of the database 130 and/or of the processing device 150 may be included within the metadata associated with each curated data model 133c. In other implementations, such information may be retrieved from the configuration data 120. In still other implementations, execution of the model modification module 245 may cause the processor(s) 155 of the processing device 150 to query the database 130 and/or other sources of information within the processing device 150.

It should also be noted that, in some implementations, it may be that at least some parsing of metadata and/or data value contents may be repeated and/or delayed until after at least some initial changes of the first pass have been preemptively applied to generate the pre-processed data model 133p from the selected data model 133s. This is to address the fact that the manner in which information in a data structure is organized and/or represented therein may impede efforts to identify and interpret that information. Thus, it may be that at least some text information within the selected data model 133s and/or its associated metadata is unable to be successfully fully parsed until after initial changes to formatting, syntax, organization, encoding, etc. of text have been applied. Thus, the provision of indications of textual attributes that have been identified as present to the vectorization module 243 may be delayed until the parsing of text following the preemptive application of initial changes of the first pass has occurred.

It should be further noted that, in some implementations, whether or not any initial change is applied to the selected data model 133s to generate the pre-processed data model 133p therefrom may be conditioned on the outcome of scoring the degree of compliance of the selected data model 133s to the standardized or learned template to which the selected data model 133s is to conform. More specifically, in executing the model modification module 245, and before any of initial change of the first pass is applied, the processor(s) 155 may be caused to use the determinations made of which attributes of that template are already present in the selected data model 133s versus which are not already present to derive a compliance score of the degree to which the selected data model 133s, without any changes made thereto, is already in compliance with that template.

In calculating the compliance score, the processor(s) 155 may retrieve relative weightings associated with each of the attributes of that template from the weighting values 127. Such relative weightings may be used to in the performance of the calculation to give greater weight to attributes that are indicated by those relative weightings to be present in the curated data models 133c with greater frequency and/or to be the subject of more rigorous compliance efforts than other attributes.

Regardless of whether such weighting is employed in the calculation of such a compliance score, the compliance score may be compared to a predetermined threshold level of compliance. If the threshold level is at least met, then it may be determined that the selected data model 133s is already sufficiently compliant to the requirements for attributes of the template to which the selected data model 133s is to conform, and therefore, no initial changes to effect greater compliance are needed. Following such a determination, another data model 133n or 133c may then be selected to become the selected data model 133s. However, if the compliance score does not meet or exceed the predetermined threshold, then the processor(s) 155 may be caused to proceed with applying at least one initial change of the first pass as described above. Additionally, the metadata of the pre-processed data model 133p may generated to include an indication of the compliance score and/or other information indicative of the degree to which the pre-processed data model 133p improves upon the compliance of the selected data model 133s.

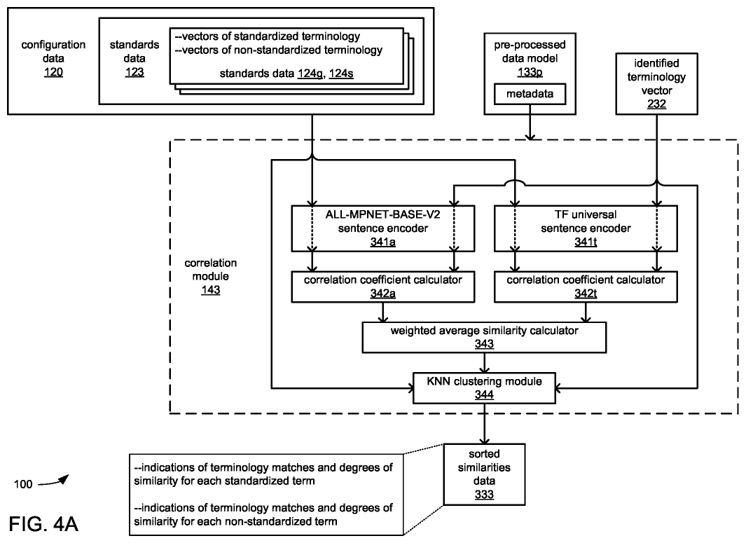

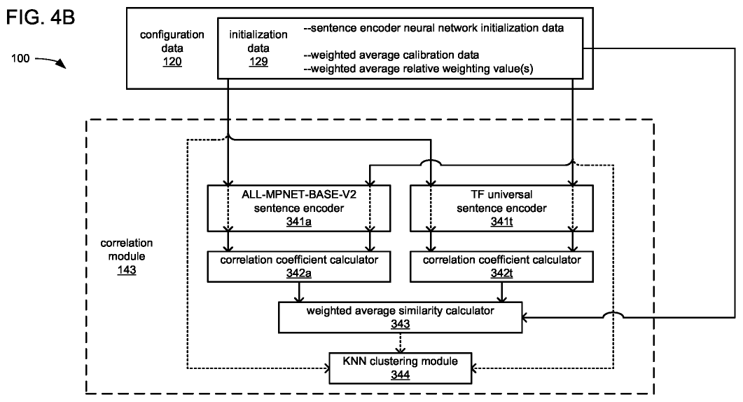

FIGS. 4A-B, taken together, present aspects of the operation of the correlation module 143 to begin the performance of the second pass of analyses according to examples of the present disclosure. In the example of FIGS. 4A-B, the correlation module 143 may include an ALL-MPNET-BASE-V2 sentence encoder 341a, a TensorFlow universal sentence encoder (TF-USE) 341t, correlation coefficient calculators 342a and 342t, a weighted average similarity calculator 343, and a KNN clustering module 344.

Turning to FIG. 4A, using indications of which standards are applicable from the metadata of the pre-processed data model 133p, each one of the corresponding standards data 124g and/or 124s within the configuration data 120 may be searched for any vectors of terminology that are indicated as being standards compliant, and for any vectors of terminology that are indicated as not being standards compliant. Such vectors retrieved from the configuration data 120 may then be compared to each of the identified terminology vector(s) 232.

More specifically, in executing the ALL-MPNET-BASE-v2 sentence encoder 341a, the processor(s) 155 of the processing device 150 may be caused to encode each identified terminology vector 232 and each vector retrieved from the configuration data 120 to generate corresponding sentence embeddings that are provided to the correlation coefficient calculator 342a. In executing the correlation coefficient calculator 342a, the sentence embedding generated from each identified terminology vector 232 may be compared to each sentence embedding that is generated from one of the vectors retrieved from the configuration data 120. From each of these comparisons, at least one cosine-based correlation coefficient may be generated that each provide an indication of degree of correlation therebetween.

In similar manner, in executing the TF-USE 341t, the processor(s) 155 may be caused to again encode each identified terminology vector 232 and each vector retrieved from the configuration data 120 to generate corresponding sentence embeddings that are provided to the correlation coefficient calculator 342t. In executing the correlation coefficient calculator 342t, the sentence embedding generated from each identified terminology vector 232 may be compared to each sentence embedding that is generated from one of the vectors retrieved from the configuration data 120. From each of these other comparisons, at least one other cosine-based correlation coefficient may be generated that each provide an indication of degree of correlation therebetween.

Each pair of corresponding correlation coefficients (i.e., one from each of the correlation coefficient calculators 342a and 342t) may then be provided as paired inputs to the weighted average similarity calculator 343. In executing the weighted average similarity calculator 343, the processor(s) 155 may assign predetermined weighting values to each correlation coefficient in each pair, and then derive a weighted average correlation score therefrom.

Although both of the sentence encoders 341a and 341t may be based on neural networks, the ALL-MPNET-BASE-V2 sentence encoder 341a supports 512 dimensional vectors, while the TF-USE 341t supports 768 dimensional vectors. This gives the TF-USE 341t a slight advantage in word recognition accuracy over the ALL-MPNET-BASE-V2 sentence encoder 341a for shorter sentences. In contrast, the ALL-MPNET-BASE-V2 sentence encoder 341a is given a slight advantage in word recognition accuracy over the TF-USE 341t for longer sentences. Using both of these sentence encoders in parallel and combining their results enables getting the benefits of the differing features of each.

Alternatively, or additionally, advantage is able to be taken of the differing features of each of the sentence encoders 341a and 341t to identify outlier indications of matches, thereby enabling such outlier indications to be filtered out. For example, it may be that a comparison of encodings generated from an identified terminology vector 232 and a vector retrieved from the configuration data 120 generated by one of the encoders 341a or 341t indicates of a match in terminology having been found therebetween, while a comparison of encodings generated from the same two vectors by the other of the encoders 341a or 341t does not indicate that match. The weighted average similarity calculator may be configured to respond to such a discrepancy in comparison results for the same pair of vectors by discounting such an indication of a match as an outlier, and may do so without the expenditure of processing resources to generate a weighted average correlation score therefrom.

The weighted average correlation scores are provided to the KNN clustering module 344, along with the corresponding identified technology vector 232 and each of the vectors of standardized or non-standardized terminology retrieved from the configuration data 120. The KNN clustering module 344 may implement a variant of the k-nearest neighbor algorithm that has been enhanced to use the weighted average correlation scores to identify matches between the terminology within the corresponding identified terminology vector 232 and the terminology within each of the vectors retrieved from the configuration data 120. The enhanced algorithm may also sort the identified matches in order of their relative degrees of similarity.

Thus, in executing the KNN clustering module 344, the processor(s) 155 may be caused to generate a sorted similarities data 333 as an output of the second pass of analyses that includes indications of matches of terminology found between an identified technology vector 232 and a vector of standardized terminology retrieved from the configuration data 120. It may be that separate indications are provided for matches of terminology that are compliant with the applicable standards, and for matches in terminology that are not compliant. It may also be that such indications of matches are organized in order of their relative degrees of similarity.

It should be noted that, in executing the KNN clustering module 344, it may be that a minimum threshold degree of similarity is imposed such that the sorted similarities data 333 is caused to not include any match having a degree of similarity that did not at least meet the threshold. The sorted similarities data 333 may then provided as an input to the recommendation module 145.

Turning to FIG. 4B, in some implementations, the configuration data 120 may include initialization data 129 that may include data for initializing the neural networks on which each of the sentence encoders 341a and 341t may be based at a time prior to use of the system 100.

Alternatively, or additionally, the initialization data 129 may include data for calibrating the relative weightings to be employed by the weighted average similarity calculator 343 during operation of the system 100. More specifically, the initialization data 129 may include a set of paired text feature vectors to be provided as inputs to the sentence encoders 341a and 341t to cause the generation of corresponding pairs of correlation coefficients for input to the weighted average similarity calculator. The initialization data 129 may also include a corresponding set of known correct weighted average correlation scores to be provided to the weighted average similarity calculator 343. In executing the weighted average similarity calculator 343 in an initialization mode, the processor(s) 155 of the processing device 150 may be caused to use the corresponding combinations of pairs of correlation coefficients and known correct weighted average correlation scores to derive the weighting value(s) to be used for generating weighted average correlation scores during normal operation of the system 100. It should be noted that in various differing implementations, each such weighting value may implement weighting curves, instead of a simple numeric weighting ratio value.

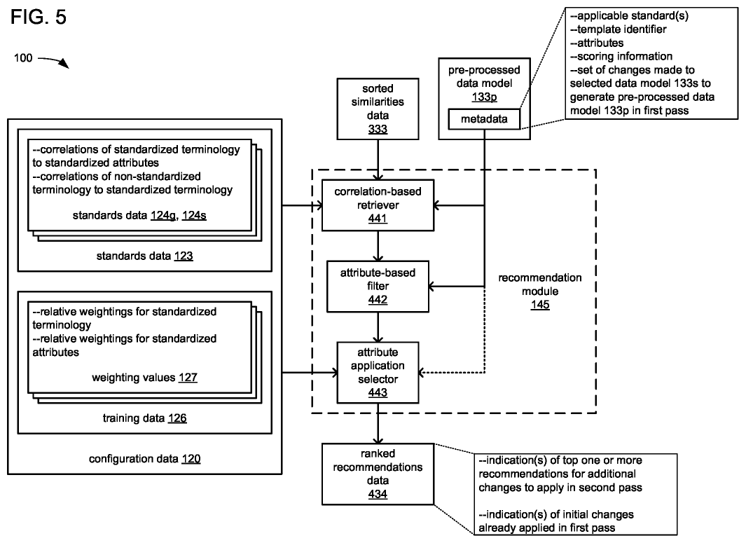

FIG. 5 presents aspects of the operation of the recommendation module 145 to perform more of the second pass of analyses according to examples of the present disclosure. In the example of FIG. 5, the recommendation module 145 may include a correlation-based retriever 441, an attribute-based filter 442, and an attribute application selector 443.

In executing the correlation-based retriever 441, the processor(s) 155 of the processing device 150 may be caused to search the standards data 142g and/or 142s for specifications of correlations between terminology that is identified in the sorted similarities data 333 as present within the pre-processed data model 133p and other attributes. In so doing, indications within the metadata of the pre-processed data model 133p concerning which standards are applicable may be used to limit such searches to just the instances of the standards data 124g and/or 124s that are associated with the applicable standards.

More specifically, for each standardized term that is identified in the sorted similarities data 333 as being present within the pre-processed data model 133p, the instances of the standards data 124g and/or 124s for the applicable standards may be searched for indications of correlations between that standardized term and another attribute that is required to also be present along with that term. In this way, a particular standardized term that is identified as present within the pre-processed data model 133p may serve as a trigger for applying a requirement that another particular attribute (e.g., a data type, a formatting detail, a particular delimiter, etc.) must also be present.

Also, for each non-standardized term that is identified in the sorted similarities data 333 as being present within the pre-processed data model 133p, the instances of the standards data 124g and/or 124s for the applicable standards may be searched for indications of correlations between that non-standardized term and a standardized term that is required to replace the non-standardized term. In this way, a particular non-standardized term that is identified as present within the pre-processed data model 133p may serve as a trigger for its own replacement with the standardized term to which it is correlated. It should be noted that, following the retrieval of such indications of correlations of non-standardized terms to standardized terms, each of those standardized terms may then be used to search for a correlation to another attribute that is required to also be present. In this way, a particular non-standardized term that is identified as present within the pre-processed data model 133p may serve as an indirect trigger for a requirement that another particular attribute must also be present.

Following the identification of a set of attributes that are each correlated to a standardized term or non-standardized term identified as present within the pre-processed data model 133p, indications of the set of attributes may then be provided to the attribute-based filter 442. In executing the attribute-based filter 442, the processor(s) 155 may be caused to compare each attribute within that set to indications within the metadata of what attributes are already present within the pre-processed data model 133p. Where an attribute within the set is identified as already present within the pre-processed data model 133p, the processor(s) 155 may be caused to remove it from the set. In this way, the set of attributes is reduced to including just those that are not already present within the pre-processed data model 133p such that action would be required to add them to the pre-processed data model 133p.

Following the reduction of the set of attributes to just those that are not already present within the pre-processed data model 133p, indications of that reduced set of attributes may then be provided to attribute application selector 443. In executing the attribute application selector 443, the processor(s) 155 may be caused to retrieve, from the configuration data 120, relative weightings indicative of relative levels of priority for the application of each additional change that may be made to the pre-processed data model 133p to add a particular attribute thereto. It should be noted that such additional changes may include changes to terminology to replace non-standardized terminology with standardized terminology.

The processor(s) 155 may be caused to use the retrieved relative levels of priority to identify the highest priority additional change(s) that are to be recommended for application to the pre-processed data model 133p as second pass changes to cause the pre-processed data model 133p to have at least one additional attribute in compliance with applicable standard(s). As previously discussed, in some embodiments, it may be that just the single highest priority additional change is to be recommended to be applied as part of the second pass. However, in other embodiments, it may be that up to a particular predetermined quantity (e.g., up to 10) of the highest priority additional changes are to be recommended to be applied as part of the second pass.

In further executing the attribute application selector, the processor(s) 155 may be caused to generate a ranked recommendations data 434 that includes indications of the highest priority additional change(s) to be recommended to be applied to the pre-processed data model 133p. The ranked recommendations data 434 may then provided as an input to the UI module 147.

It should be noted that, in some implementations, whether or not the ranked recommendations data 434 is generated to enable a presentation of recommendations for additional change(s) to be applied to the pre-processed data model 133p in the second pass may be conditioned on the outcome of scoring the degree of compliance of the pre-processed data model 133p to the standardized or learned template to which the pre-processed data model 133p is to conform. More specifically, in executing the attribute application selector 443, and before the ranked recommendations data 434 is generated and/or provided to UI module 147, the processor(s) 155 may be caused to use the determinations made of which attributes of that template are already present in the pre-processed data model 133p versus which are not already present to derive a compliance score of the degree to which the pre-processed data model 133p, without any changes made thereto, is already in compliance with that template.

In calculating the compliance score, the processor(s) 155 may use relative weightings associated with each of the attributes of that template to give greater weight to attributes that are indicated by those relative weightings to be present in the curated data models 133c with greater frequency and/or to be the subject of more rigorous compliance efforts than other attributes. The processor(s) may also use scoring information concerning the earlier compliance score calculation that may have been performed during the first pass to avoid repeating at least a portion of that earlier calculation.

Regardless of whether such weighting is employed in the calculation of such a compliance score, the compliance score may be compared to a predetermined threshold level of compliance. If the threshold level is at least met, then it may be determined that the pre-processed data model 133p is already sufficiently compliant to the requirements for attributes of the template to which the pre-processed data model 133p is to conform, and therefore, no additional changes to effect greater compliance are needed. Following such a determination, no further analyses of the second pass may be performed, and another data model 133n or 133c may then be selected to become the selected data model 133s. However, if the compliance score does not meet or exceed the predetermined threshold, then the processor(s) 155 may be caused to proceed with generating and/or providing the ranked recommendations data 434 to the UI module 147 to enable completion of the second pass analyses, and to enable the performance of second pass changes to the pre-processed data model 133p.

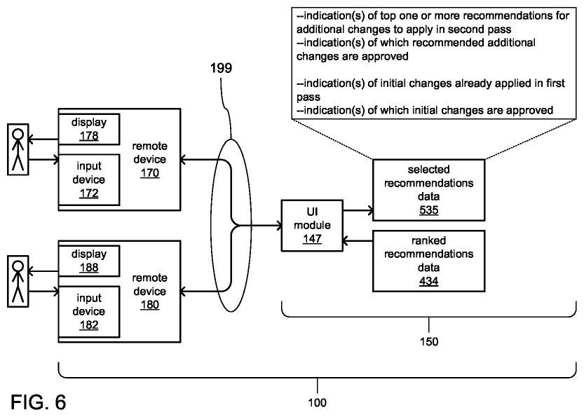

FIG. 6 presents aspects of the operation of the UI module 147 to interact with the remote devices 170 and/or 180 through the network 199 according to examples of the present disclosure.

In executing the UI module 147, the processor(s) 155 of the processing device 150 may be caused to operate the network interface 159 to transmit the ranked recommendations data 434 to the remote device 170 via the network 199. In this way, the remote device 170 may be caused to use its display 178 and input device 172 (e.g., a keyboard, mouse, stylus, touch pad, etc.) to provide a user interface to present the recommended additional change(s) indicated in the ranked recommendations data 434, along with a prompt for input concerning which one(s) thereof are approved for being applied (if any). The processor(s) 155 may then be caused to operate the network interface 159 to await a response indicative of such input via the network 199.

Upon receiving such input from the remote device 170, further execution of the UI module 147 may cause the processor(s) 155 to operate the network interface 159 to also transmit the ranked recommendations data 434 to the remote device 180, along with indications of which one(s) of the proposed additional change(s) have been approved. In a similar manner, the remote device 180 may be caused to use its display 188 and input device 182 to provide a user interface to present the recommended additional change(s) indicated in the ranked recommendations data 434, along indications of which one(s) thereof have been approved and a prompt for input concerning any changes to those approvals. The processor(s) 155 may then be caused to operate the network interface 159 to await a response indicative of such input via the network 199.

Upon receiving such input from the remote device 180, further execution of the UI module 147 may cause the processor(s) 155 to generate a selected recommendations data 535 indicative of which additional change(s) were recommended, along with indications of which one(s) are ultimately approved. The selected recommendations data 535 may then be provided to the training module 148.

It should be noted that, in some implementations, operators of the remote devices 170 and/or 180 may additionally be presented with indications of what initial changes of the first pass have already been made to the selected data model 133s by the pre-processing module 142 (see FIG. 1C) to generate the corresponding pre-processed data model 133p. Such operators may also be presented with a prompt for input concerning which one(s) of such initial changes are approved and/or which one(s) of such initial changes are disapproved.

In support of this, and referring briefly back to FIG. 5, execution of the attribute application selector 443 may additionally cause the processor(s) 155 to generate the ranked recommendations data 434 to additionally include indications of what initial changes of the first pass were already made by the model modification module 245 of the pre-processing module 142 (see FIG. 3C). Also, and returning to FIG. 6, execution of the UI module 147 may additionally cause the processor(s) 155 to generate the selected recommendations data 535 to additionally include indications of which ones of those initial changes are approved and/or disapproved based on input received from the remote devices 170 and/or 180 in response to the prompts for such input.

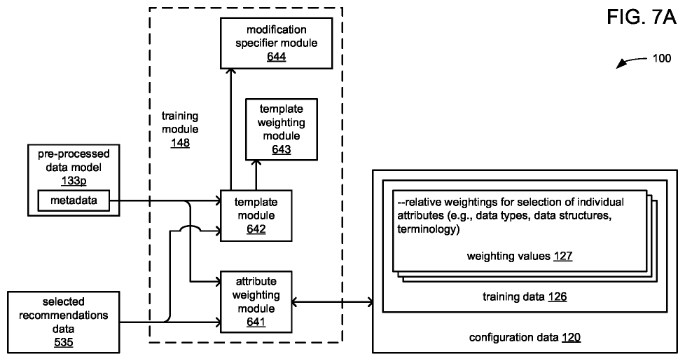

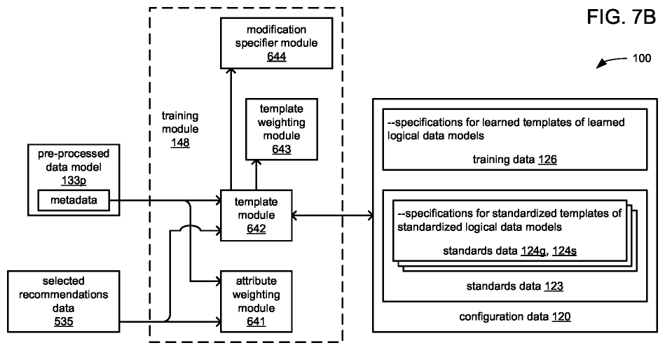

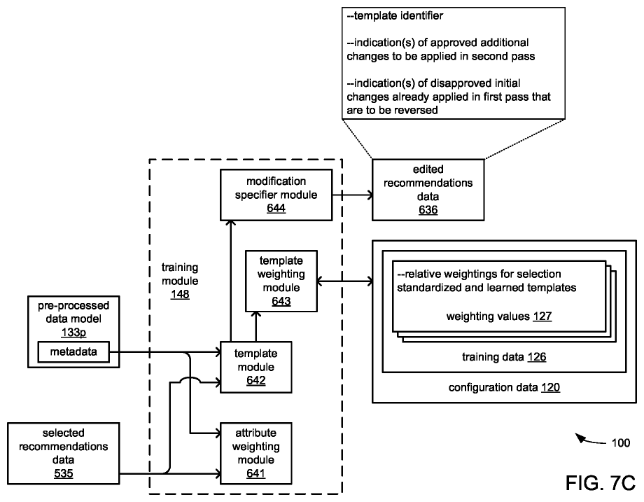

FIGS. 7A-C, taken together, present aspects of the operation of the training module 148 to train the processing device 150 as part of completing the second pass analyses, and as part of implementing machine learning within the system 100 according to examples of the present disclosure. In the example of FIGS. 7A-C, the training module 148 may include an attribute weighting module 641, a template module 642, a template weighting module 643, and a modification specifier module 644.

Turning to FIG. 7A, in executing the attribute weighting module 641, the processor(s) 155 of the processing device 150 may be caused to use the indications in the selected recommendations data 535 of which one(s) of the recommended additional changes are approved and/or disapproved for being applied to the pre-processed data model 133p to update various relative weightings among the weighting values 127 for relative priorities for applying changes to add various attributes to data models. In so doing, the processor(s) 155 may also use indications within the metadata of the pre-processed data model 133p of what initial changes have already been applied to the selected data model 133s to generate the pre-processed data model 133p therefrom to update more of such weightings.

As previously discussed, in implementations where operators of the remote devices 170 and/or 180 are prompted to provide input indicative of approvals or disapprovals of initial changes already performed to generate the pre-processed data model 133p from the selected data model 133s, the selected recommendations data 535 may include indications of which one(s) of those initial changes are approved or disapproved. In such implementations, further execution of the attribute weighting module 641 may cause the processor(s) 155 to use such indications in the selected recommendations data 535 in updating the relative weightings associated therewith.

Turning to FIG. 7B, in executing the template module 642, the processor(s) 155 may be caused to use indications in the metadata of the pre-processed data model 133p of what attributes are currently present in the pre-processed data model 133p, along with the indications in the selected recommendations data 535 of what additional changes are approved to be applied in the second pass, to derive the set of attributes that will be present within the pre-processed data model 133p after the approved additional changes (if there are any) have been applied. In so doing, in implementations in which the selected recommendations data 535 includes indications of what initial changes already applied in the first pass are approved, the processor(s) 155 may also be caused to derive the set of attributes that will be present within the pre-processed data model 133p after disapproved one(s) of those initial changes (if any) have been reversed.

In further executing the template module 642, the processor(s) 155 may be caused to use the set of attributes that the pre-processed data model 133p will have to again search for at least one existing template for data models having the same set of attributes. Again, the processor(s) 155 may be caused to limit the search to templates associated with the applicable standards, as indicated in the metadata. In this way, an opportunity is provided for the selection of a different template that may be more appropriate for the set of attributes that is about to be present within the pre-processed data model 133p.

If a template among the standardized templates or among the learned templates associated with the applicable standards is found that has a set of attributes that matches the set of attributes that will be present within the pre-processed data model 133p, then an identifier of that particular template may be relayed to the template weighting module 643 and to the model modification module 644. If more than one of such templates are found, then the selection of which template to use may be based on relative weightings among the weighting values 127 for the relative frequency of use of each of those templates. It should be noted that such a search may result in the selection of the very same template on which the pre-processed data model 133p is already based.

However, if no such template is found among either of the standardized templates or the learned templates associated with the applicable standards, then the set of attributes that will be present within the pre-processed data set 133p may be used to define a new learned template that may be added to the specifications for learned templates maintained within the training data 126. Following the addition of such a new learned template to the specifications for learned templates within the training data 126, an identifier of that new learned template may be relayed to the template weighting module 643 and/or to the model modification module 644.

Turning to FIG. 7C, upon receiving the identifier of what standardized template or what learned template the pre-processed data model 133p is to conform to, execution of the template weighting module 643 may cause the processor(s) 155 to update various relative weightings among the weighting values 127 for the relative frequencies of use of the standardized and learned templates.

Also upon receiving the identifier of what standardized template or what learned template the pre-processed data model 133p is to conform to, execution of the modification specifier module 644 may cause the processor(s) 155 to generate an edited recommendations data 636 that includes an indication of what template was identified by the template module 642. Also included in the edited recommendations data 636 may be indications of the approved one(s) of the additional changes to be applied to the pre-processed data model 644 (if any), and/or indications of the disapproved one(s) of the initial changes that are to be reversed (if any). The processor(s) 155 may then relay the edited recommendations data 636 to the post-processing module 149.

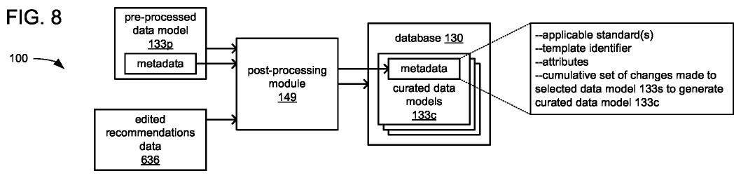

FIG. 8 presents aspects of the operation of the post-processing module 149 to apply second pass changes according to examples of the present disclosure. Upon receiving the edited recommendations data 636, and in a manner somewhat similar to the model modification module 245 of the pre-processing module 142 (see FIGS. 3A-C), the processor(s) 155 may be caused by execution of the post-processing module 149 to use the template identifier, the indications of approved additional changes to the pre-processed data model 133p (if any), and/or the indications of disapproved initial changes to the pre-processed data model 133p (if any) to generate a curated data model 133c from the pre-processed data model 133p.

More specifically, where the template identified in the edited recommendations data 636 is different from the one on which the pre-processed data model 133p is already based, then further changes may be applied to the pre-processed data model 133p to cause it to conform to the new template. Such changes may be in addition to any approved one(s) of the additional changes (if any) that are also indicated in the edited recommendations data 636.

Regardless of what changes are applied to the pre-processed data model 133p to generate a curated data model 133c, the resulting curated data model 133c may then be stored within the database 130. Where this resulting curated data model 133c is an updated version of a curated data model 133c that was already stored in the database, then that older version may be replaced.

The storage 160 of the processing device 150 may include any of a variety of types of non-transitory computer readable storage medium implemented using any of a variety of storage technologies, including and not limited to, any electronic, magnetic, optical, or other physical storage device that stores executable instructions. For example, the storage 150 may include random access memory (RAM), an electrically-erasable programmable read-only memory (EEPROM), a storage drive, an optical disc, or the like. The storage 150 may be encoded to store executable instructions (e.g., instructions of the model maintenance routine 140) that cause a processor (e.g., the processor(s) 155) to perform operations according to examples of the disclosure.

The processor(s) 155 of the processing device 150 may include memory to either permanently or temporarily store a set of instructions (e.g., instructions of the model maintenance routine 140). The processor(s) 155 execute the instructions that are stored in the memory or memories in order to process data. The set of instructions may include various instructions that perform a particular task or tasks, such as those tasks described above. Such a set of instructions for performing a particular task may be characterized as a software program.

The present disclosure may employ a software stack to enlist the underlying tools, frameworks, and libraries used to build and run example applications of the present disclosure. Such a software stack may include PHP, React, Cassandra, Hadoop, Swift, etc. The software stack may include both frontend and backend technologies including programming languages, web frameworks servers, and operating systems. The frontend may include JavaScript, HTML, CSS, and UI frameworks and libraries. In one example, a MEAN (MongoDB, Express.js, Angular JS, and Node.js) stack may be employed. In another example, a LAMP (Linux, Apache, MySQL, and PHP) stack may be utilized.

Any suitable programming language can be used to implement the routines of particular examples including Java, Python, JavaScript, C, C++, assembly language, etc. Different programming techniques can be employed such as procedural or object oriented. The routines may execute on specialized processors.

As used in the description herein and throughout the claims that follow, “a”, “an”, and “the” include plural references unless the context clearly dictates otherwise. Also, as used in the description herein and throughout the claims that follow, the meaning of “in” includes “in” and “on” unless the context clearly dictates otherwise. While the above is a complete description of specific examples of the disclosure, additional examples are also possible. Thus, the above description should not be taken as limiting the scope of the disclosure which is defined by the appended claims along with their full scope of equivalents.

1. A system comprising:
at least one processor; and
a storage to store instructions that, when executed by the at least one processor, cause the at least one processor to perform operations comprising:
analyze a data model to identify a first set of attributes present within the data model;
based on the first set, identify a data model standard with which the data model is to comply, wherein the standard requires a second set of attributes to be present in complying data models;
compare the first and second sets to identify a third set of attributes required by the standard, but not present in the data model;
based on weightings of priority of the attributes of the third set, identify at least one highest priority change to apply to the data model to increase compliance of the data model with the standard;
present a user interface (UI) requesting approval to apply the at least one highest priority change to the data model; and
apply the at least one highest priority change to the data model and update at least one of the weightings of priority of the attributes of the third set based on whether approval to apply the at least one highest priority change is received via the UI.

2. The system of claim 1, wherein:
compliance of the data model to the standard comprises compliance of the model to a template for data models associated with the standard;
the template specifies a subset of the attributes of the second set of attributes;
identifying the standard based on the first set of attributes present within the data model comprises identifying the template as a template with which the data model is to comply; and
identifying the template comprises the at least one processor being caused to perform operations comprising:
derive a degree of match between the first set of attributes present within the data model and the subset of the second set of attributes specified by the template; and
compare the degree of match to a predetermined minimum degree of match.

3. The system of claim 2 wherein the at least one processor is further caused to update the weighting of frequency of use of the template based on the identification of the template as the template with which the data model is to comply.

4. The system of claim 2, wherein the degree of match between the first set of attributes present within the data model and the subset of the second set of attributes specified by the template is at least partially based on the weightings of priority of each attribute of the subset of the second set of attributes.

5. The system of claim 1, wherein:
the first set of attributes present within the data model comprises a non-textual attribute and a textual attribute;
the non-textual attribute comprises at least one of:
a manner of organizing data values in the data model;
a choice of delimiter used in organizing data values in the data model;
a manner of encoding data values in the data model; or
a manner of representing data values in the data model; and
the at least one processor is caused to perform further operations comprising:
prior to presenting the UI, apply an initial change to the data model to cause the data model to include the non-textual attribute; and
after the application of the initial change, and prior to presenting the UI, parse the data model to identify the textual attribute as among the first set of attributes present within the data model.

6. The system of claim 5, wherein the at least one processor is caused to perform further operations comprising:
generate the UI to request an indication of whether the application of the initial change to the data model is disapproved; and
reverse the application of the initial change to the data model and update a weighting of priority of the non-textual attribute based on whether disapproval of the application of the initial change is received via the UI.

7. The system of claim 1, wherein:
the data model comprises metadata descriptive of the first set of attributes present within the data model; and
analyzing the data model to identify the first set of attributes comprises using a Bayesian parser to parse at least one of:
contents of the data model to identify textual attributes within the first set of attributes; or
the metadata to identify textual indications of at least a subset of the attributes of the first set of attributes.

8. The system of claim 1, wherein:
the first set of attributes present within the data model comprises a textual attribute;
the textual attribute comprises at least one of:
a column label;
a row label;
a label of a subject of the data model; or
a label of an index within the data model;
the standard comprises a first glossary of standardized terminology, and specifications of correlations between a first subset of words within the first glossary and a first subset of attributes of the second set of attributes;
each attribute of the first subset of attributes is conditionally required to be present in the data model if a correlated word within the first subset of words is present in the data model; and
identifying the at least one highest priority change comprises the at least one processor being caused to perform further operations comprising:
search for the textual attribute within the first subset of words; and
in response to finding the textual attribute within the first subset of words, identify the correlated attribute within the first subset of attributes, and determine whether the correlated attribute is already present within the data model.

9. A non-transitory machine-readable storage medium including executable instructions stored thereon which, when executed by at least one processor, cause the at least one processor to perform operations comprising:
analyze a data model to identify a first set of attributes present within the data model;
based on the first set, identify a data model standard with which the data model is to comply, wherein the standard requires a second set of attributes to be present in complying data models;
compare the first and second sets to identify a third set of attributes required by the standard, but not present in the data model;
based on weightings of priority of the attributes of the third set, identify at least one highest priority change to apply to the data model to increase compliance of the data model with the standard;
visually present, on a display of a remote device, a request for approval to apply the at least one highest priority change to the data model; and
apply the at least one highest priority change to the data model and update at least one of the weightings of priority of the attributes of the third set based on whether approval to apply the at least one highest priority change is received from the remote device.

10. The non-transitory machine-readable storage medium of claim 9, wherein:
compliance of the data model to the standard comprises compliance of the model to a template for data models associated with the standard;
the template specifies a subset of the attributes of the second set of attributes;
identifying the standard based on the first set of attributes present within the data model comprises identifying the template as a template with which the data model is to comply; and
identifying the template comprises the at least one processor being caused to perform operations comprising:
derive a degree of match between the first set of attributes present within the data model and the subset of the second set of attributes specified by the template; and
compare the degree of match to a predetermined minimum degree of match.

11. The non-transitory machine-readable storage medium of claim 10, wherein the at least one processor is further caused to update the weighting of frequency of use of the template based on the identification of the template as the template with which the data model is to comply.

12. The non-transitory machine-readable storage medium of claim 10, wherein the degree of match between the first set of attributes present within the data model and the subset of the second set of attributes specified by the template is at least partially based on the weightings of priority of each attribute of the subset of the second set of attributes.

13. The non-transitory machine-readable storage medium of claim 9, wherein:
the first set of attributes present within the data model comprises a non-textual attribute and a textual attribute;
the non-textual attribute comprises at least one of:
a manner of organizing data values in the data model;
a choice of delimiter used in organizing data values in the data model;
a manner of encoding data values in the data model; or
a manner of representing data values in the data model; and
the at least one processor is caused to perform further operations comprising:
prior to presenting the request on the display, apply an initial change to the data model to cause the data model to include the non-textual attribute; and
after the application of the initial change, and prior to presenting the request, parse contents of the data model to identify the textual attribute as among the first set of attributes present within the data model.

14. The non-transitory machine-readable storage medium of claim 13, wherein the at least one processor is caused to perform further operations comprising:
present, on the display, a request for an indication of whether the application of the initial change to the data model is disapproved; and
reverse the application of the initial change to the data model and update a weighting of priority of the non-textual attribute based on whether disapproval of the application of the initial change is received from the remote device.

15. The non-transitory machine-readable storage medium of claim 9, wherein:
the data model comprises metadata descriptive of the first set of attributes present within the data model; and
analyzing the data model to identify the first set of attributes comprises using a Bayesian parser to parse at least one of:
contents of the data model to identify textual attributes within the first set of attributes; or
the metadata to identify textual indications of at least a subset of the attributes of the first set of attributes.

16. The non-transitory machine-readable storage medium of claim 9, wherein:
the first set of attributes present within the data model comprises a textual attribute;
the textual attribute comprises at least one of:
a column label;
a row label;
a label of a subject of the data model; or
a label of an index within the data model;
the standard comprises a glossary of standardized terminology, and specifications of correlations between words within the glossary and a subset of attributes of the second set of attributes;
each attribute of the subset of attributes is conditionally required to be present in the data model if a correlated word within the glossary is present in the data model; and
identifying the at least one highest priority change comprises the at least one processor being caused to perform further operations comprising:
search for the textual attribute within the glossary; and
in response to finding the textual attribute within the glossary, identify the correlated attribute within the subset of attributes, and determine whether the correlated attribute is already present within the data model.

17. A computer-implemented method for updating data models comprising:
analyzing a data model to identify a first set of attributes present within the data model;
based on the first set, identifying a data model standard with which the data model is to comply, wherein the standard requires a second set of attributes to be present in complying data models;
comparing the first and second sets to identify a third set of attributes required by the standard, but not present in the data model;
based on weightings of priority of the attributes of the third set, identifying at least one highest priority change to apply to the data model to increase compliance of the data model with the standard;
visually presenting, on a display of a remote device, a user interface (UI) requesting approval to apply the at least one highest priority change to the data model;
receiving, at a processor, and from the remote device, a response to the request; and
applying the at least one highest priority change to the data model and updating at least one of the weightings of priority of the attributes of the third set based on whether the response comprises approval to apply the at least one highest priority change.

18. The computer-implemented method of claim 17, wherein:
compliance of the data model to the standard comprises compliance of the model to a template for data models associated with the standard;
the template specifies a subset of the attributes of the second set of attributes;
identifying the standard based on the first set of attributes present within the data model comprises identifying the template as a template with which the data model is to comply; and
identifying the template comprises performing operations comprising:
deriving a degree of match between the first set of attributes present within the data model and the subset of the second set of attributes specified by the template; and
comparing the degree of match to a predetermined minimum degree of match.

19. The computer-implemented method of claim 17, wherein:
the first set of attributes present within the data model comprises a non-textual attribute and a textual attribute;
the non-textual attribute comprises at least one of:
a manner of organizing data values in the data model;
a choice of delimiter used in organizing data values in the data model;
a manner of encoding data values in the data model; or
a manner of representing data values in the data model; and
the method further comprises:
prior to presenting the UI, applying an initial change to the data model to cause the data model to include the non-textual attribute; and
after the application of the initial change, and prior to presenting the UI, parsing contents of the data model to identify the textual attribute as among the first set of attributes present within the data model.

20. The computer-implemented method of claim 17, wherein:
the first set of attributes present within the data model comprises a textual attribute;
the textual attribute comprises at least one of:
a column label;
a row label;
a label of a subject of the data model; or
a label of an index within the data model;
the standard comprises a glossary of standardized terminology, and specifications of correlations between words within the glossary and a subset of attributes of the second set of attributes;
each attribute of the subset of attributes is conditionally required to be present in the data model if a correlated word within the glossary is present in the data model; and
identifying the at least one highest priority change comprises performing operations comprising:
searching for the textual attribute within the glossary; and
in response to finding the textual attribute within the glossary, identifying the correlated attribute within the subset of attributes, and determining whether the correlated attribute is already present within the data model.
